(19) United States
(12) Patent Application Publication
(10) Pub. No.: US 2006/0278987 A1
(43) Pub. Date: Dec. 14, 2006

(54) INTEGRATED CIRCUIT HAVING A PROGRAMMABLE CONDUCTIVE PATH ON EACH CONDUCTIVE LAYER AND RELATED METHOD OF MODIFYING A VERSION NUMBER ASSIGNED TO THE INTEGRATED CIRCUIT

(76) Inventors: Yung-Chieh Yu, Hsin-Chu Hsien (TW); Po-Sen Wang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/160,136

(22) Filed: Jun. 10, 2005

(51) Int. Cl. H01L 23/48

(52) U.S. Cl. 257/758

(57) ABSTRACT

An integrated circuit has an identification circuit for providing a read-only logic value for identifying the integrated circuit. The identification circuit includes a plurality of programmable stages for determining the read-only logic value. Each of the programmable stages includes a logic cell and a conductive path. The logic cell has an input node connected to an input terminal of the programmable stage, an inverting output node, and a non-inverting output node. The logic value at the non-inverting output node is the same as the logic value at the input node, and the logic value at the inverting output node is different from the logic value at the input node. The conductive path is positioned on one of the conductive layers, and is programmed for selectively connecting either one of the inverting output node or the non-inverting output node of the logic cell to an output terminal of the programmable stage.

### BACKGROUND

The invention relates to version identification for an integrated circuit, and more particularly, to an integrated circuit having a programmable conductive path positioned on each conductive layer and a related method of modifying the version number assigned to the integrated circuit.

Due to the hasty improvement of the semiconductor manufacturing technology, designing an integrated circuit becomes increasingly complex which in turn increases the opportunity of modifying the layout of the integrated circuit. In general, the integrated circuit is modified by changing the mask of the conductive layers (e.g., the metal layer or via layer) in the integrated circuit to modify the layout design. The changes made to the current layout design cause the following integrated circuit to be different from the current one. In order to distinguish different versions of the integrated circuit, a version number, which is usually a set of read-only logic values stored in memory within the integrated circuit, is utilized for providing the identification information to determine the particular version of a number of designed integrated circuits. More specifically, in the pertinent art the version number is stored by providing one voltage level at each of a plurality of external terminals. The particular voltage level, which represents one of the bits defining the version number, is typically provided through hard-wired connections to the voltage sources. These connections are regularly routed in at least one of the metal or via layers.

However, the conductive layers changed by the circuit designer are usually different from the conductive layers having the connections routed thereon for defining the version number of the integrated circuit. That is, for modifying the circuit design, a conventional integrated circuit will generally require that changes be made to additional conductive layers when changing the version number. For example, the layout of a first conductive layer is modified to change the integrated circuit design. If a second conductive layer different from the first conductive layer is used to define the version number, the layout of the second conductive layer has to be modified due to the change made to the integrated circuit design. Therefore, two new masks must be re-designed and re-produced for amending the layouts of the first and second conductive layers. Because the mask is quite expensive, the changes made to additional conductive layers for the version number modification lead to a significantly increased cost for fabricating the integrated circuits.

### SUMMARY

It is therefore one of many objectives of the claimed invention to provide an integrated circuit having a programmable conductive path positioned on each conductive layer and a related method of modifying the version number assigned to the integrated circuit, to significantly reduce the cost of fabricating the integrated circuits.

According to an embodiment of the claimed invention, an integrated circuit is disclosed. The integrated circuit comprises a plurality of conductive layers each having a defined layout; and an identification circuit for providing a read-only logic value, which is either logic zero or logic one, utilized for identifying an attribute of the integrated circuit. The identification circuit comprises: a plurality of programmable stages, electrically connected in a series, for generating the read-only logic value at an output terminal of the last programmable stage when an input terminal of the first programmable stage receives a preset logic value. Each of the programmable stages comprises a logic cell and a conductive path. The logic cell has an input node connected to an input terminal of the programmable stage, an inverting output node, and a non-inverting output node. The logic value at the non-inverting output node is the same as the logic value at the input node, and the logic value at the inverting output node being different from the logic value at the input node. The conductive path is programmed for selectively connecting either one of the inverting output node or the non-inverting output node of the logic cell to an output terminal of the programmable stage.

The integrated circuit of the claimed invention provides a programmable stage for each conductive layer. Therefore, the layout for a conductive layer can be amended for changing characteristic of the integrated circuit in conjunction with the version number. This will significantly reduce the cost of fabricating the integrated circuits.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a section view of an integrated circuit according to one embodiment of the present invention.

FIG. 2 shows a schematic diagram illustrating an identification circuit formed within the integrated circuit for defining the version number of the integrated circuit according to an embodiment of the present invention.

FIG. 3 is a diagram illustrating an embodiment of implementing the logic cell shown in FIG. 2.

### DETAILED DESCRIPTION

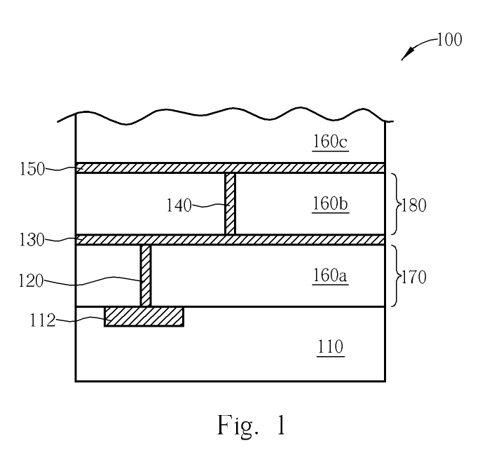

Please refer to FIG. 1. FIG. 1 illustrates a section view of an integrated circuit 100 according to an embodiment of the present invention. A wafer 110 is positioned at the lowest layer of the integrated circuit 100, where the wafer 110 is a layer of silicon material in which various transistor devices are created through the diffusion of P and N type dopants. The configuration and operation of transistor devices are well known to those skilled in the art; detailed description is omitted here for brevity. Please note that the wafer 110 includes a portion of diffused material to create a conductive layer 112, which allows defining different conductive paths within the wafer 110 according to a specific masking process. Continually, a layer of silicon dioxide insulating material 160a is deposited on the top of the wafer 110. Please note that one silicon dioxide insulating layer 160a, 160b, 160c in this present invention is deposited between two adjacent metal layers for providing insulating protection in the integrated circuit 100. After the deposition of the silicon dioxide insulating layer 160a, an etching mask is placed over the silicon dioxide insulating layer 160a and an etching process is activated to provide at least an opening through the silicon dioxide insulating layer 160a. Then, metallic material is deposited on the silicon dioxide insulating layer 160a for forming a via 120 connecting the diffused portion (i.e., the conductive layer 112) of the wafer 110 and a metal layer 130. The metal layer 130 is deposited through a mask on the top of the silicon dioxide insulating layer 160a, and has connection paths defined by the applied mask.

Similarly, after the deposition of the silicon dioxide insulating layer 160b, an etching mask is placed over the silicon dioxide insulating layer 160b and an etching process is activated to provide at least an opening through the silicon dioxide insulating layer 160b. Then, metallic material is deposited on the silicon dioxide insulating layer 160b for forming a via 140. A metal layer 150 is deposited through a mask on the top of the silicon dioxide insulating layer 160b, and has connection paths defined by the applied mask. As shown in FIG. 1, the via 140 connects the metal layer 130 to the metal layer 150. Commonly, the silicon dioxide insulating layers 160a, 160b having vias 120, 140 are so-called via layers 170, 180 respectively.

Please note that each conductive layer has a defined layout and the number of the conductive layers formed in the integrated circuit 100 is dependent on the circuit design. FIG. 1 shows only two metal conductive layers 130, 150 and two via conductive layers 120, 140 for illustrative purposes and should not be considered limitations of the present invention. Further, the structure shown in FIG. 1 is for illustrative purpose and is not limitations of the present invention. In addition, the conductive layer is not limited to being named in metal or via layer or formed by metallic material, other specific materials and names (e.g. poly, diffusion, or contact layer) also can be utilized in forming and naming the conductive layer, but the basic function for conducting is the same.

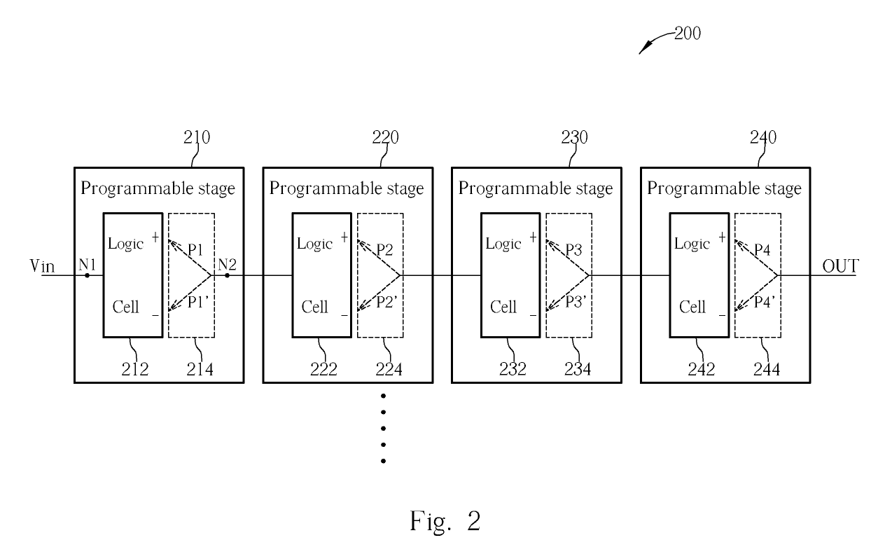

Please refer to FIG. 2 in conjunction with FIG. 1. FIG. 2 shows a schematic diagram illustrating an identification circuit 200 formed within the integrated circuit 100 for defining the version number of the integrated circuit 100 according to an embodiment of the present invention. Please note that for simplicity FIG. 2 illustrates only a small portion of the identification circuit 200. That is, the portion illustrated includes circuitry for providing a single bit of a version number for the integrated circuit 100. It is known to those skilled in the art that the circuitry shown in FIG. 2 can be easily modified to meet the requirement of representing a version number of N bits (i.e., N is an integer greater than or equal to one). The identification circuit 200 includes a plurality of programmable stages 210, 220, 230, 240 connected in a series. In this embodiment, each programmable stage shown in FIG. 2 is programmed through a specific conductive layer shown in FIG. 1. For example, assume the integrated circuit 100 only has four conductive layers (i.e., metal layers 130, 150 and via layers 170, 180). Programmable stages 210, 220, 230, 240 are respectively programmed through the metal layer 150, the via layer 180, the metal layer 130, and the via layer 170. As shown in FIG. 2, each of the programmable stages 210, 220, 230, 240 has a logic cell 212, 222, 232, 242 and a conductive path 214, 224, 234, 244. The conductive path 214 could be programmed to be either path P₁ or P₁′; the conductive path 224 could be programmed to be either path P₂ or P₂′; the conductive path 234 could be programmed to be either path P₃ or P₃′; and the conductive path 244 could be programmed to be either path P₄ or P₄′. The programmable stages 210, 220, 230, 240 have the same structure and functionality. Taking the programmable stage 210 for example, the logic cell 212 in the programmable stage 210 makes an output at the inverting output node (−) have a logic value different from a logic value of an input node N₁ and makes an output at the non-inverting output node (+) have a logic value identical to the logic value of the input node N₁. In other words, based on an input inputted into the logic cell 212, the logic cell 212 provides an inverting output and a non-inverting output accordingly. Please note that the above-mentioned paths P₁, P₂, P₃, and P₄ represent the paths connecting to the non-inverting output nodes (+) in the programmable stage 210,220,230, and 240 respectively; and the above-mentioned paths P₁′, P₂′, P₃′, and P₄′ represent the paths which connect to the inverting output node (−) in the programmable stage 210,220,230, and 240 respectively. Accordingly, the conductive path 214 in the programmable stage 210 is programmed for selectively connecting either one of the inverting output node (−) or the non-inverting output node (+) of the logic cell 212 to an output node N₂ of the programmable stage 210. The key feature of the present invention is that these conductive paths 214, 224, 234, 244 are respectively placed on conductive layers 150, 140, 130, 120 of the integrated circuit 100. As to the logic cells 212, 222, 232, 242, they are fabricated within the integrated circuit 100 and have input and output nodes routed to corresponding conductive layers. Taking the logic cell 222 for example, its input node is routed to the metal layer 150 and its output nodes are both routed to the via layer 180. Formation of the logic cell 212 in the identification circuit 200 and routing of the connecting paths through conductive layers is well known to those skilled in this art; further description is omitted here for brevity. The operation of the identification circuit 200 is detailed as follows.

If an input voltage Vᵢₙ is provided, the programmable stages 210, 220, 230, 240 operate to determine the final read-only logic value OUT generated from the integrated circuit 100. Note that the input voltage Vᵢₙ can be placed in two different voltage levels (e.g., 0V and +5V) which represent bits “0” and “1”. However, the voltage level assigned to the input voltage Vᵢₙ for version identification may alter according to different circuit designs. Suppose that one bit of the version number identified by the identification circuit 200 for the current circuit design of the integrated circuit 100 is defined to be “1” as the input voltage Vᵢₙ corresponding to “1” is provided. Under this condition, for example, the programmable stages 210, 220, 230, 240 are programmed, causing paths P₁′, P₂′, P₃, P₄ to be routed on corresponding conductive layers, that is, the metal layer 150, the via layer 180, the metal layer 130 and the via layer 170. Therefore, if the input voltage Vᵢₙ corresponding to “1” is provided to the logic cell 212, the logic cell 212 makes its inverting output node be “0” and non-inverting output node be “1”. As mentioned before, both output nodes are routed to the metal layer 150. Because the conductive path 214 is programmed to be the path P₁′ on the metal layer 150, “0” outputted from the inverting output node is passed to the next programmable stage 220 through a connection routed between the conductive path 214 and the logic cell 222. Then, the logic cell 222 makes its inverting output node be “1” and non-inverting output node be “0”. In addition, both output nodes are routed to the via layer 180. Because the conductive path 224 is programmed to be the path P₂′ on the via layer 180, “1” outputted from the inverting output node is passed to the next programmable stage 230 through a connection routed between the conductive path 224 and the logic cell 232.

The logic cell 232 makes its inverting output node be “0” and non-inverting output node be “1”. As mentioned above, both output nodes are routed to the metal layer 130. Because the conductive path 234 is programmed to be the path P₃ on the metal layer 130, “1” outputted from the non-inverting output node is passed to the next programmable stage 240 through a connection routed between the conductive path 234 and the logic cell 242. Finally, the logic cell 242 makes its inverting output node have “0” and non-inverting output node have “1”. As mentioned before, both output nodes are routed to the via layer 170. Because the conductive path 244 is programmed to be the path P₄ on the via layer 170, the read-only logic value OUT generated from the identification circuit 200 becomes the desired value “1” for one bit of the version number.

It should be noted that, the final read-only logic value OUT is determined by the number of inverting output nodes presented on the signal-transmitting path. According to the above description, the input voltage passes through four conductive layers shown in FIG. 2, and the number of passed inverting output nodes is two. Therefore, the final read-only logic value OUT has the same logic value as the input voltage Vᵢₙ due to an even number of passed inverting output nodes. On the contrary, if the number of passed inverting output nodes is an odd number, the final read-only value OUT is sure to have a logic value different from that possessed by the input voltage Vᵢₙ. Based on this rule, each bit of the version number can be correctly defined through programming the conductive paths within the programmable stages. For example, if a change made to the integrated circuit 100 causes layout modifications to a plurality of conductive layers such as the metal layers 150, 130 and the via layer 180, the conductive paths 214, 224, 234 can be properly programmed to adjust the number of inverting output nodes on the signal transmitting path, thereby correctly changing the read-only logic value OUT as desired.

It is clear that the conductive paths 214, 224, 234, 244 are capable of controlling the read-only logic value OUT. For example, if one of the conductive paths 214, 224, 234, 244 changes its routing design, the read-only logic value OUT is inversed, changing from “1” to “0”. Therefore, if the designer wants to modify the layout of the metal layer 150 to correct some design errors of the integrated circuit 100, the version number of the integrated circuit 100 can be easily changed by re-programming the conductive paths of the programmable stages routed on the same metal layer 150. For example, if one bit of the version number defined by the read-only logic value OUT shown in FIG. 2 requires modification, the conductive path 214 routed on the metal layer 150 is re-programmed to be the other path P₁′, resulting “0” assigned to the read-only logic value OUT as the input voltage Vᵢₙ having “1” is inputted. Therefore, a new integrated circuit having a new version number is fabricated through a minimum extent of amendments made given the expensive masks and costs associated with integrated circuit fabrication; cost is greatly decreases.

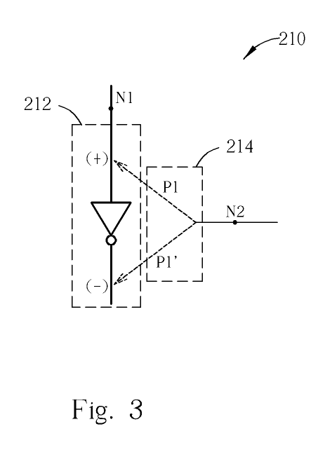

In the present invention, the logic cell 212, 222, 232, 242 is used for providing an inverting output and a non-inverting output. Any circuitry capable of performing the above signal processing can be implemented as the logic cell 212, 222, 232, 242. Please refer to FIG. 3. FIG. 3 is a diagram illustrating an embodiment of implementing the logic cell 212 shown in FIG. 2. The desired signal processing can be embodied by a well-known inverter. That is, an inverter is used to function as the logic cell 212 with an inverting output node (−) and a non-inverting output node (+). Please note that the inverter is only used to serve as an example and is not a limitation of the present invention. Other embodiments of the present disclosure utilizing different inverting function elements, for example a NAND gate, a NOR gate, an AND-OR-NOT (AOI) gate, an OR-AND-NOT (OAI) gate, or an inverting output MUX, are also possible. As shown in FIG. 3, the programmable path P₁ or P₁′ can be properly routed on the metal layer 150 to control which of the inverting output node (−) and the non-inverting output node (+) is selected according to the design requirement.

In contrast to the related art integrated circuit for version identification, the integrated circuit of the present invention provides a programmable stage for each conductive layer. Therefore, the layout for a conductive layer can be amended to change a characteristic of the integrated circuit in conjunction with the version number and greatly decreasing the cost of the fabrication process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit, comprising:
a plurality of conductive layers each having a defined layout; and
an identification circuit for providing a read-only logic value, which is either logic zero or logic one, utilized for identifying an attribute of the integrated circuit, the identification circuit comprising:
a plurality of programmable stages, electrically connected in series, for generating the read-only logic value at an output terminal of the last programmable stage when an input terminal of the first programmable stage receives a preset logic value, each programmable stage comprising:
a logic cell having an input node connected to an input terminal of the programmable stage, an inverting output node, and a non-inverting output node, the logic value at the non-inverting output node being the same as the logic value at the input node, the logic value at the inverting output node being different from the logic value at the input node; and
a conductive path, positioned on one of the conductive layers, the conductive path being programmed for selectively connecting either one of the inverting output node or the non-inverting output node of the logic cell to an output terminal of the programmable stage.

2. The integrated circuit of claim 1, wherein the non-inverting output node of the logic cell is the input node of the logic cell.

3. The integrated circuit of claim 1, wherein the logic cell is an inverter.

4. The integrated circuit of claim 1, wherein one of the conductive layers is a metal layer.

5. The integrated circuit of claim 1, wherein one of the conductive layers is a via layer.

6. The integrated circuit of claim 1, wherein one of the conductive layers is a poly layer.

7. The integrated circuit of claim 1, wherein one of the conductive layers is a diffusion layer.

8. The integrated circuit of claim 1, wherein one of the conductive layers is a contact layer.

9. The integrated circuit of claim 1, wherein the attribute of the integrated circuit is a version number of the integrated circuit.

10. The integrated circuit of claim 1, wherein the attribute of the integrated circuit is a K-bit number and K is an integer.

11. The integrated circuit of claim 10, wherein the integrated circuit comprises K identification circuits, each for generating one of bit values of the K-bit number.

12. A method of modifying a read-only logic value, which is either logic zero or logic one, utilized for identifying an attribute of an integrated circuit when a layout of a specific conductive layer of the integrated circuit is changed, the method comprising:
providing the integrated circuit with a plurality of programmable stages, electrically connected in series, for determining the read-only logic value outputted at an output terminal of the last programmable stage when an input terminal of the first programmable stage receives a preset logic value;
in each programmable stage, forming:
a logic cell having an input node connected to an input terminal of the programmable stage, an inverting output node, and a non-inverting output node, the logic value at the non-inverting output node being the same as the logic value at the input node, the logic value at the inverting output node being different from the logic value at the input node; and
a conductive path, positioned on one of a plurality of conductive layers of the integrated circuit, the conductive path being programmed for selectively connecting one of the inverting output node and the non-inverting output node of the logic cell to an output terminal of the programmable stage; and
in response to the change of the layout of the specific conductive layer, re-programming a conductive path of a specific programmable stage so as to modify the read-only logic value.

13. The method of claim 12, wherein the conductive path of the specific programmable stage is positioned on the specific conductive layer.

14. The method of claim 12, wherein the step of forming the logic cell comprises an inverter.

15. The method of claim 12, wherein one of the conductive layers is a metal layer.

16. The method of claim 12, wherein one of the conductive layers is a via layer.

17. The method of claim 12, wherein one of the conductive layers is a poly layer.

18. The method of claim 12, wherein one of the conductive layers is a diffusion layer.

19. The method of claim 12, wherein one of the conductive layers is a contact layer.

20. The method of claim 12, wherein the attribute of the integrated circuit is a version number of the integrated circuit.

21. The method of claim 12, wherein the attribute of the integrated circuit is a K-bit number and K is an integer.

22. The method of claim 12, wherein the integrated circuit comprises K identification circuits, each for generating one of bit values of the K-bit number.
